(19) United States
(12) Patent Application Publication
(10) Pub. No.: US 2005/0240838 A1
(43) Pub. Date: Oct. 27, 2005

(54) Semiconductor memory device having code bit cell array

(76) Inventor: Hitoshi Iwai, Fujisawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/928,168

(22) Filed: Aug. 30, 2004

(30) Foreign Application Priority Data
Apr. 23, 2004 (JP) 2004-128575

(51) Int. Cl. G11C 29/00; H03M 13/00

(52) U.S. Cl. 714/718

(57) ABSTRACT

A semiconductor memory device includes a data bit cell array in which a plurality of memory cells each to store a data bit is arranged, a test circuit which detects and analyzes a command that contains test pattern information, a syndrome counter which counts the number of error corrections which are made on data bits read from the data bit cell array in a test made on the basis of the test pattern information. The device further includes an output circuit which outputs a line fault detect signal when the count in the syndrome counter reaches a predetermined value.

### CROSS-REFERENCE TO RELATED APPLICATIONS

This application is based upon and claims the benefit of priority from prior Japanese Patent Application No. 2004-128575, filed Apr. 23, 2004, the entire contents of which are incorporated herein by reference.

### BACKGROUND OF THE INVENTION

1. Field of the Invention

The present invention relates to a semiconductor memory device. More specifically, the present invention relates to a semiconductor memory device having a code bit cell array that stores code bits (also called parity data) for error correction.

2. Description of the Related Art

Conventionally, an example of a semiconductor memory device equipped with an error correction code (ECC) circuit is a device adapted to record the number of error corrections (the error correction count) (see, for example, WO (Published International Application) 01/022232). This device is adapted to deduce the cause of errors from the number of error corrections and perform either alternate processing or refresh processing accordingly.

A semiconductor memory device equipped with an ECC circuit, for example, a dynamic random access memory (DRAM) is normally provided with a code bit cell array. That is, the DRAM equipped with the ECC circuit has a code bit cell array to store code bits in addition to a data bit cell array to store write data.

The error correcting capability of such an ECC circuit is determined by the number of code bits for the number of data bits (write data or read data). Specifically, to make single-bit error correction, eight code bits are required for 128 data bits (per line). With single-bit error correction, in a read operation by way of example, a fault of up to one bit in data bits (128 bits) is corrected and then read as normal data. This DRAM is thus regarded in appearance as a good quality product.

In contrast, with multiple-bit error correction, that is, with error correction of data bits in which two or more bit faults are present, code bits are required in units of several tens of bits. For this reason, it takes a long time to generate code bits and correct errors. In addition, the area of the code bit cell array to store the code bits increases.

In general, the number of bit faults that occur anew after repair is small. For this reason, the capability of the ECC circuit is sufficient if it can correct a single-bit error per line. Therefore, the principal ECC circuit to be built into general DRAMs seems to be one that has a single-bit-error correction/double-bit error detecting function. Thus, the DRAMs can be prevented from increasing in size. However, the DRAMs each equipped with an ECC circuit which has a single-bit-error correction/double-bit error detecting function have a problem that the presence of a line fault (row and column faults) which is error-corrected by the ECC circuit at the test time for mass production cannot be recognized from the exterior.

Here, in DRAMs each having an ECC circuit built in, data bits corresponding to one line communicated between the data bit cell array and the ECC circuit are transferred simultaneously in the column direction. This is desirable in terms of efficiency. The reason is that trying to make error detection and correction on data bits corresponding to one line in the row direction in a batch needs two or more sense operations. As a result, a lot of time will be needed. Even if transfer is made in the column direction, data bits corresponding to one line are transferred simultaneously. If not simultaneously, then the memory operation will be delayed by the additional time taken. Accordingly, the batch transfer of data bits corresponding to one line in the column direction is the most efficient method. According to this method, it becomes possible to simultaneously read data bits corresponding to one line through sense amplifiers (S/A).

With the DRAM arranged as described above, an especially important problem is that, in the case of row faults, faulty data are read out without being corrected, whereas, in the case of column faults, error-corrected normal data are read out. That is, in the case of the so-called single-column (one column) fault in which there are two or more bit faults only on the same column, only one bit fault is present in data bits read out at a time in the column direction. In the case of the single-column fault, therefore, it becomes possible to make error correction through the ECC circuit which has the single-bit error correction/double-bit error detecting function. In contrast, in the case of the so-called one-row fault in which two or more bit faults are present on the same row, two or more bit faults are present in data bits read out at a time in the column direction. In the case of the one-row fault, therefore, the ECC circuit which has the single-bit error correction/double-bit error detecting function cannot perform error correction.

Thus, in the DRAM with the built-in ECC circuit having the single-bit error correction/double-bit error detecting function, the ECC circuit can automatically correct a one-column fault in particular, but it is impossible to know from the exterior whether the DRAM contains a one-column fault. For this reason, when a one-column fault exists, the ECC circuit having the single-bit error correction/double-bit error detecting function cannot sufficiently cope with bit faults which occur later. Suppose here that, in a DRAM which contains a one-column fault, a new bit fault has occurred anew on the same column through soft error after shipment. In such a case, the new bit fault is not corrected and the faulty data remains as it is.

As described above, that a one-column fault is contained within the error correction unit (for example, 136 bits, the sum of 128 data bits and 8 code bits, are taken to be one unit) of the ECC circuit having the single-bit error correction/double-bit error detecting function is equivalent to there being no ECC circuit for a bit fault other than a column fault that occurs within the unit at and after the test time for mass production. It is therefore desirable that a semiconductor memory device which contains a one-column fault that can be corrected by the ECC circuit at the test time for mass production be rejected as a faulty product or be remedied through a redundancy circuit.

Conventionally, a proposal has been made to deduce the cause of errors from the number of error corrections. With a semiconductor memory device having the ECC circuit, however, it is impossible to externally recognize whether a column fault that can be corrected at the test time for mass production exists.

### BRIEF SUMMARY OF THE INVENTION

According to a first aspect of the present invention, there is provided a semiconductor memory device which comprises a data bit cell array in which a plurality of memory cells each to store a data bit is arranged; a test circuit which detects and analyzes a command that contains test pattern information; a syndrome counter which counts the number of error corrections which are made on data bits read from the data bit cell array in a test made on the basis of the test pattern information; and an output circuit which outputs a line fault detect signal when the count in the syndrome counter reaches a predetermined value.

According to a second aspect of the present invention, there is provided a semiconductor memory device which comprises a data bit cell array in which a plurality of memory cells are arranged to store data bits; an error correction code (ECC) circuit which detects and corrects errors in data bits read from the data bit cell array; a code bit cell array which stores code bits required for the ECC circuit to perform error detection and correction; a test circuit which detects and analyzes a command containing test pattern information and a count limiting value for line fault detection; a syndrome counter which counts the number of error corrections that are made on data bits read from the data bit cell array in a test made under the test pattern information; an output circuit which outputs a line fault detect signal when the count in the syndrome counter reaches the count limiting value; and a first address register which temporarily stores the address of a line which is the subject of the test.

According to a third aspect of the present invention, there is provided a semiconductor memory device which comprises a data bit cell array in which a plurality of memory cells are arranged to store data bits; an error correction code (ECC) circuit which detects and corrects errors in data bits read from the data bit cell array; a code bit cell array which stores code bits required for the ECC circuit to perform error detection and correction; a test circuit which detects and analyzes a command containing test pattern information and a count limiting value for line fault detection; a syndrome counter which counts the number of error corrections that are made on data bits read from the data bit cell array in a test made under the test pattern information; an output circuit which outputs a line fault detect signal when the count in the syndrome counter reaches the count limiting value; a first address register which temporarily stores the address of a line which is the subject of the test; and a second address register which temporarily stores the address of a line which is the subject of the test and outputs the stored address to outside of the device as the address of a faulty line when the count in the syndrome counter reaches the count limiting value.

### BRIEF DESCRIPTION OF THE SEVERAL VIEWS OF THE DRAWING

FIG. 1 is a basic block diagram of a DRAM equipped with an ECC circuit having a single-bit error correction/double-bit error detecting function according to a first embodiment of the present invention;

FIG. 2A is a circuit diagram of the data bit cell array shown in FIG. 1;

FIG. 2B is a circuit diagram of the code bit cell array shown in FIG. 1;

FIG. 3 is a flowchart for use in explanation of the flow of processing involved in column fault detection in the DRAM shown in FIG. 1;

FIG. 4 is a basic block diagram of a DRAM equipped with an ECC circuit according to a second embodiment of the present invention;

FIG. 5 is a flowchart for use in explanation of the flow of processing involved in column fault detection in the DRAM shown in FIG. 4;

FIG. 6 is a basic block diagram of a DRAM equipped with an ECC circuit according to a third embodiment of the present invention;

FIG. 7 is a flowchart for use in explanation of the flow of processing involved in column fault detection in the DRAM shown in FIG. 6;

FIG. 8 is a basic block diagram of a DRAM equipped with an ECC circuit according to a fourth embodiment of the present invention; and

FIG. 9 is a flowchart for use in explanation of the flow of processing involved in column fault detection in the DRAM shown in FIG. 8.

### DETAILED DESCRIPTION OF THE INVENTION

Embodiments of the present invention will be described with reference to the accompanying drawings.

### First Embodiment

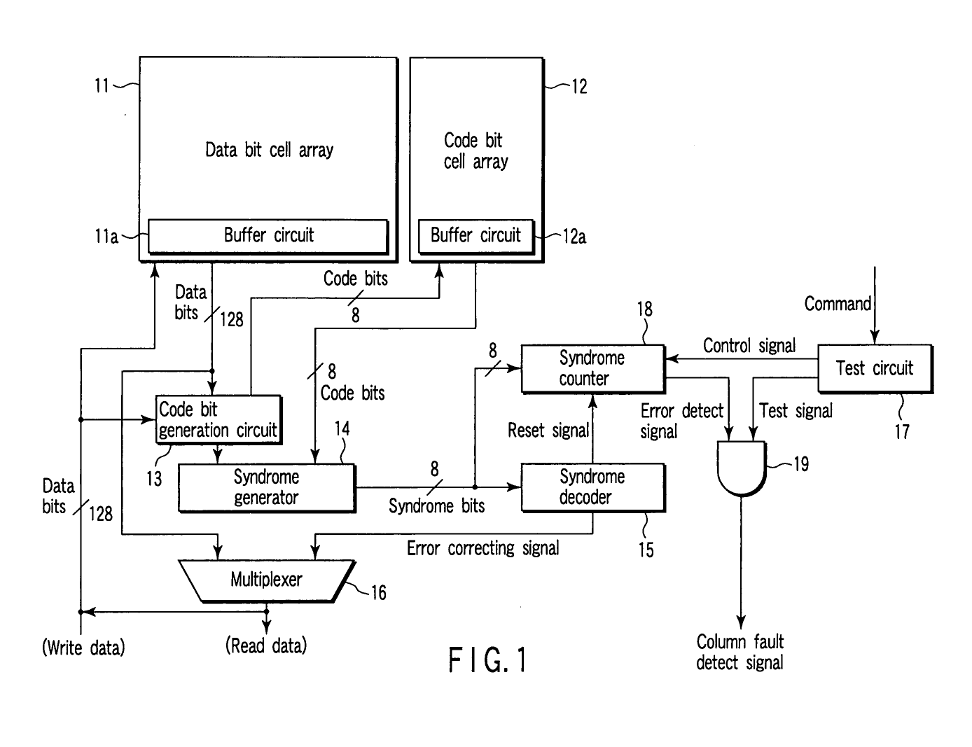

FIG. 1 shows the basic arrangement of a semiconductor memory device equipped with an ECC circuit according to a first embodiment of the present invention. The first embodiment is directed to a DRAM equipped with an ECC circuit having a single-bit error correction/double-bit error detecting function. In the first embodiment, a description is given of a case where the data length and the code length per line are set to 128 and 8 bits, respectively, and the total (136 bits) of the 128 data bits and the 8 code bits is set as an error correction unit of the ECC circuit.

As shown in FIG. 1, the DRAM equipped with the ECC circuit is configured to have a data bit cell array 11 for store write data (data bits) and a code bit cell array 12 for storing code bits. The data bit cell array 11 and the code bit cell array 12 include a buffer circuit 11a and a buffer circuit 12a, respectively.

The DRAM has a code bit generation circuit 13, a syndrome generator 14, a syndrome decoder 15, a multiplexer 16, a test circuit 17, a syndrome counter 18, and an output circuit 19. The code bit generation circuit 13 generates code bits (8 bits) from data bits (128 bits) output from the data bit cell array 11. The syndrome generator 14 checks code bits read from the code bit cell array 12 with the code bits generated by the code bit generation circuit 13 to output 8 syndrome bits. The syndrome bits contain information concerning the presence or absence of a single-bit error (bit fault) or double-bit error and, in the case of single-bit error, which bit is in error.

The syndrome decoder 15 decodes the syndrome bits output from the syndrome generator 14. If, as the result of decoding, a single-bit error is detected from the syndrome bits and it is within the error correction unit of the ECC circuit, then the syndrome decoder 15 outputs an error correcting signal to the multiplexer 16. If, on the other hand, no single-bit error is detected from the syndrome bits, then the syndrome decoder 15 outputs a reset signal to the syndrome counter 18. When supplied with the error correcting signal, the multiplexer 16 corrects the error in the data bits read from the data bit cell array 11.

The test circuit 17, when supplied with a command from a test device (not shown) at the test time for mass production, outputs a control signal and a test signal to the syndrome counter 18 and the output circuit 19, respectively. For example, the command contains a test pattern type for the mass production test which in which the ECC circuit is in operation, count information (count limiting value), etc. The test pattern type is information indicating either the row-first scan (RFS) pattern-based test or the column-first scan (CFS) pattern-based test. The count information is information indicating how many times single-bit errors are to be detected in succession by the syndrome counter 18 at the time of, for example, the RFS-pattern-based test for mass production in order to determine that a column fault has occurred. The control signal is the count information mentioned above. The test signal is one that goes high (active) at the time of, for example, the RFS-pattern-based test for mass production.

The syndrome counter 18 is adapted to count the syndrome bits (single-bit error correction) from the syndrome generator 14. When the count in the syndrome counter 18 reaches the count information, the syndrome counter 18 outputs an error detect signal (control information) to the output circuit 19. The count in the syndrome counter 18 is reset by the reset signal from the syndrome decoder 15. The output circuit 19 is comprised of, for example, an AND circuit. Based on the test signal from the test circuit 17 and the error detect signal from the syndrome counter 18, the output circuit 19 outputs a column (line) fault detect signal to the test device external to the DRAM.

In this embodiment, the ECC circuit having the single-bit error correction/double-bit error detecting function is composed of the code bit generation circuit 13, the syndrome generator 14, the syndrome decoder 15, and the multiplexer 16.

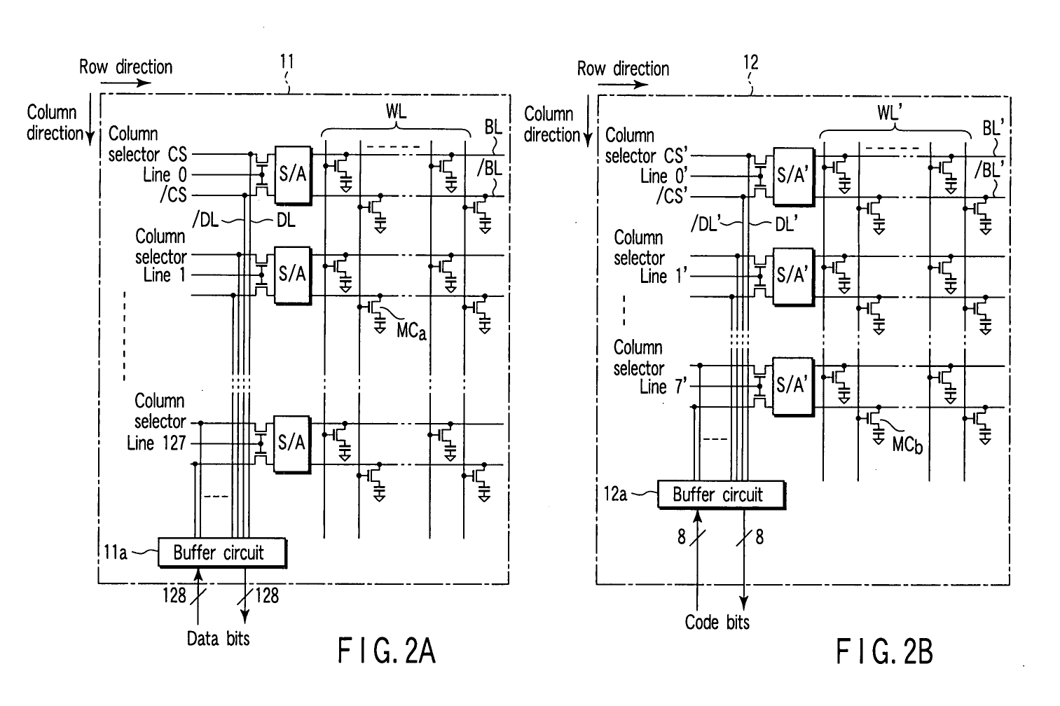

FIGS. 2A and 2B show exemplary arrangements of the data bit cell array 11 and the code bit cell array 12, respectively. The data bit cell array 11 is provided with a number of memory cells MCa to store the data bits. Each of the memory cells MCa is located at a selective one of the intersections of word lines WL and bit line pairs BL and /BL.

Each of the bit line pairs BL and /BL is connected to a corresponding sense amplifier S/A. Each of the sense amplifiers S/A is connected to a corresponding column selector pair CS and /CS. Each of the column selector pairs CS and /CS is connected to a corresponding data line pair DL and /DL. Each of the data line pairs DL and /DL is connected to the buffer circuit 11a. In this embodiment, one of the column selector pairs CS and /CS is selected by a line select signal (line 0 to line 127). Thereby, the data line pair DL and /DL and the bit line pair BL and /BL which correspond to the selected column selector pair are electrically connected to each other through the corresponding sense amplifier S/A.

The code bit cell array 12 is provided with a number of memory cells MCb to store the code bits. Each of the memory cells MCb is located at a selective one of the intersections of word lines WL′ and bit line pairs BL′ and /BL′.

Each of the bit line pairs BL′ and /BL′ is connected to a corresponding sense amplifier S/A′. Each of the sense amplifiers S/A′ is connected to a corresponding column selector pair CS′ and /CS′. Each of the column selector pairs CS′ and /CS′ is connected to a corresponding data line pair DL′ and /DL′. Each of the data line pairs DL′ and /DL′ is connected to the buffer circuit 12a. In this embodiment, one of the column selector pairs CS′ and /CS′ is selected by a line select signal (line 0′ to line 7′). Thereby, the data line pair DL′ and /DL′ and the bit line pair BL′ and /BL′ which correspond to the selected column selector pair are electrically connected to each other through the corresponding sense amplifier S/A′.

The operation of the DRAM thus configured will be described next. In a normal write operation, data bits (write data) are written into the data bit cell array 11. At this point, code bits are generated from the data bits by the code bit generating circuit 13 in the ECC circuit and then written into the code bit cell array 12.

In a normal read operation, on the other hand, data bits are read from the data bit cell array 11. The read data bits are then sent to the code bit generating circuit 13 and the multiplexer 16. The code bit generating circuit 13 generates code bits on the basis of the data bits read from the data bit cell array 11. Code bits corresponding to the data bits are read from the code bit cell array 12 and then sent to the syndrome generator 14. In the syndrome generator 14, the code bits are collated with the code bits generated by the code bit generating circuit 13.

The results of collation (syndrome bits) by the syndrome generator 14 are sent to the syndrome decoder 15. If a single-bit error is detected from the syndrome bits and it is within the error correction unit of the ECC circuit, a single-bit error in the data bits read from the data bit cell array 11 is corrected in the multiplexer 16. The error-corrected data bits are read out to the outside as read data.

The error-corrected data bits read out as read data are rewritten into the data bit cell array 11. At the same time, code bits are regenerated in the code bit generation circuit 13 and then rewritten into the code bit cell array 12.

Here, the mass production tests for a semiconductor memory device equipped with an ECC circuit will be described briefly. In the case of a semiconductor memory device equipped with an ECC circuit which has a single-bit error correction/double-bit error detecting function, among mass production tests is one that is performed in a state where the ECC circuit is in operation to test the ECC circuit itself at the same time. For example, for a test the main object of which is to improve the reliability of semiconductor memory devices, faulty cells are remedied by a redundancy circuit and then the semiconductor memory device is tested in a state where the ECC circuit is in operation. In this test, the reliability of the semiconductor memory device can be expected to increase by making the test specifications the same as those based on no ECC circuit (when the ECC circuit is not operated). For a test the main object of which is to reduce the test time, it is removed from the mass production test items supposing that a specific single-bit fault will be remedied by the ECC circuit after shipment. This allows the mass production test time to be reduced. Moreover, for a test the main object of which is to increase the manufacturing yield of semiconductor memory devices, the remedy against bit faults is made to depend largely on the ECC circuit. By so doing, the yield of semiconductor memory devices can be expected to increase.

Next, a description is given of the method of a test that is performed in a state where the ECC circuit is in operation at the mass production test time for semiconductor memory devices each equipped with the ECC circuit. In particular, in DRAMs each equipped with an ECC circuit having a single-bit error correction/double-bit error detecting function as shown in FIG. 1, the method of detecting a line (column) fault which is error corrected by the ECC circuit at the mass production test time will be described.

In the case of a mass production test, the test device knows which test pattern the test is to be performed on. In other words, a pattern program for the mass production test (test pattern) is produced from the test device. Whether the test pattern generated from the test device is the row-first scan (RFS) pattern or the column-first scan (CFS) pattern can be distinguished readily by providing the test circuit 17. The RFS pattern is one in which a scan is made first in the row direction and the CFS pattern is one in which a scan is made first in the column direction.

In particular, in a test based on the RFS pattern, error correction by the ECC circuit becomes possible when the semiconductor memory device contains a one-column fault. The error correction is made in succession.

In the first embodiment, therefore, the test circuit 17 that detects and analyzes commands from the test device is provided in the DRAM equipped with an ECC circuit having the single-bit error correction/double-bit error detecting function. In addition, the syndrome counter 18 is provided which receives a control signal from the test circuit 17 and counts syndrome bits from the syndrome generator 14. This column fault detection is made possible by regarding the situation in which error corrections are counted in succession by the syndrome counter 18 at the RFS-pattern-based test time as a column fault.

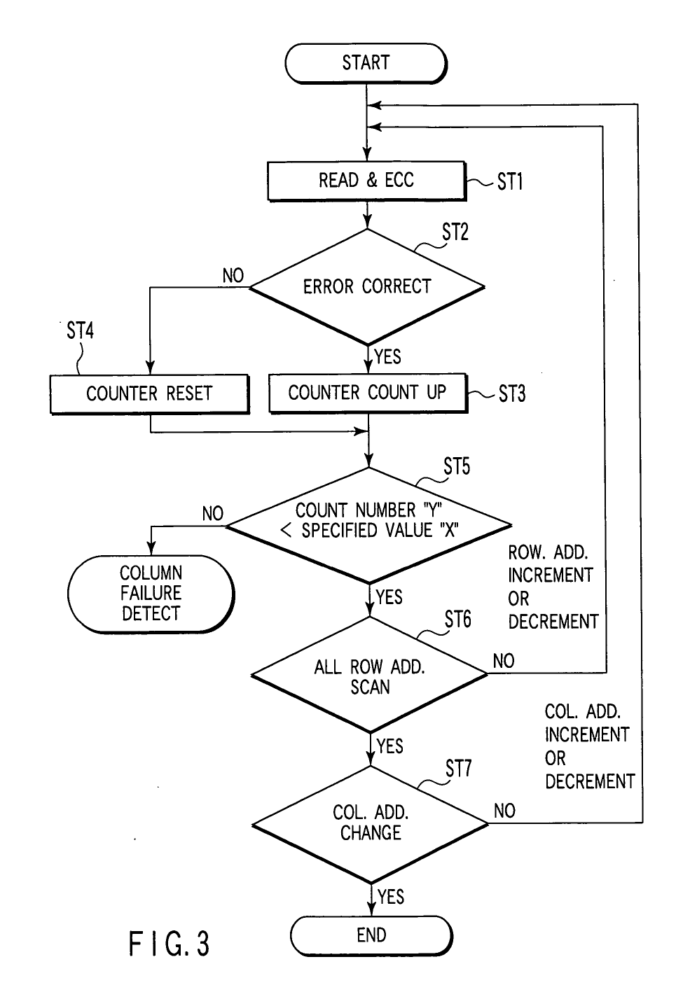

FIG. 3 shows more specifically the flow of processing involved in the column fault detection. Suppose that, at the mass production test time, the test circuit 17 detects and analyzes the RFS-pattern-based test in a state where the ECC circuit is in operation as a command from the test device (step ST1). Then, a specific value “X” as count information (count limiting value) is set in the syndrome counter 18 by a control signal from the test circuit 17.

In this state, a normal read operation is performed. The syndrome bits from the syndrome generator 14 associated with the read operation are decoded in the syndrome decoder 15 (step ST2). At the same time, the syndrome bits from the syndrome generator 14 are counted in the syndrome counter 18 (step ST3).

If a single-bit error is not detected in the syndrome decoder 15, then the count “Y” in the syndrome counter 18 is reset (step ST4). That is, when single-bit errors are not counted in succession in the syndrome counter 18 (X>Y), the count “Y” is reset once.

Suppose here that single-bit errors are counted in succession in the syndrome counter 18 and consequently the count “Y” has reached the specific value “X” (step ST5). Then, a column fault detect signal is output from the output circuit 19 to the test device.

The processes in steps ST1 through ST5 are repeated until the scanning of all the row addresses is finished (step ST6). The processes in steps ST1 through ST6 are repeated until the column address is updated (step ST7).

As described above, the mass production test in the state where the ECC is in operation allows column faults to be detected. That is, the column fault is detected by regarding the situation in which error corrections are counted in succession by the syndrome counter at the RFS-pattern-based mass-production test time as the occurrence of a column fault. It thus becomes possible to externally recognize column faults that are automatically corrected by the ECC circuit at the mass production test time. Accordingly, it becomes possible to reject or remedy a DRAM that contains column faults.

### Second Embodiment

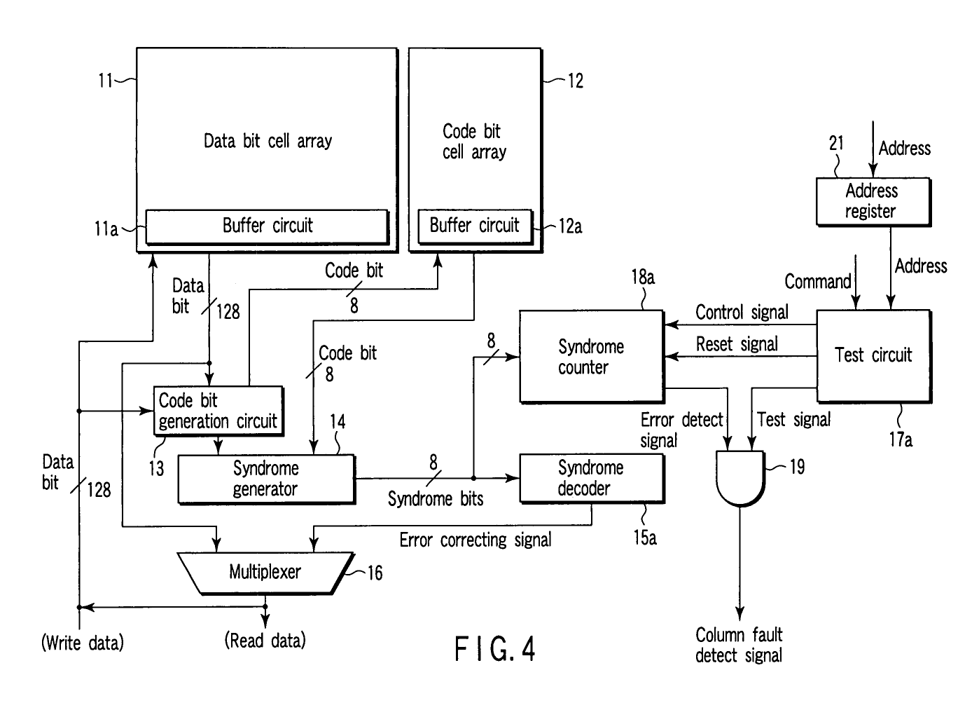

FIG. 4 shows the basic arrangement of a semiconductor memory device equipped with an ECC circuit according to a second embodiment of the present invention. The second embodiment is configured such that, in the DRAM of the first embodiment, the syndrome counter 18a is reset each time the column address is updated. In FIG. 4, corresponding parts to those in FIG. 1 are denoted by like reference numerals and detailed descriptions thereof are omitted.

As shown in FIG. 4, an address register 21 is connected to a test circuit 17a. The address register 21 holds a column address once and then outputs it to the test circuit 17a. Upon receiving a column address from the address register 21, the test circuit 17a outputs a signal to reset a syndrome counter 18a. For this reason, unlike the first embodiment shown in FIG. 1, a syndrome decoder 15a is not adapted to output a reset signal to the syndrome counter 18a.

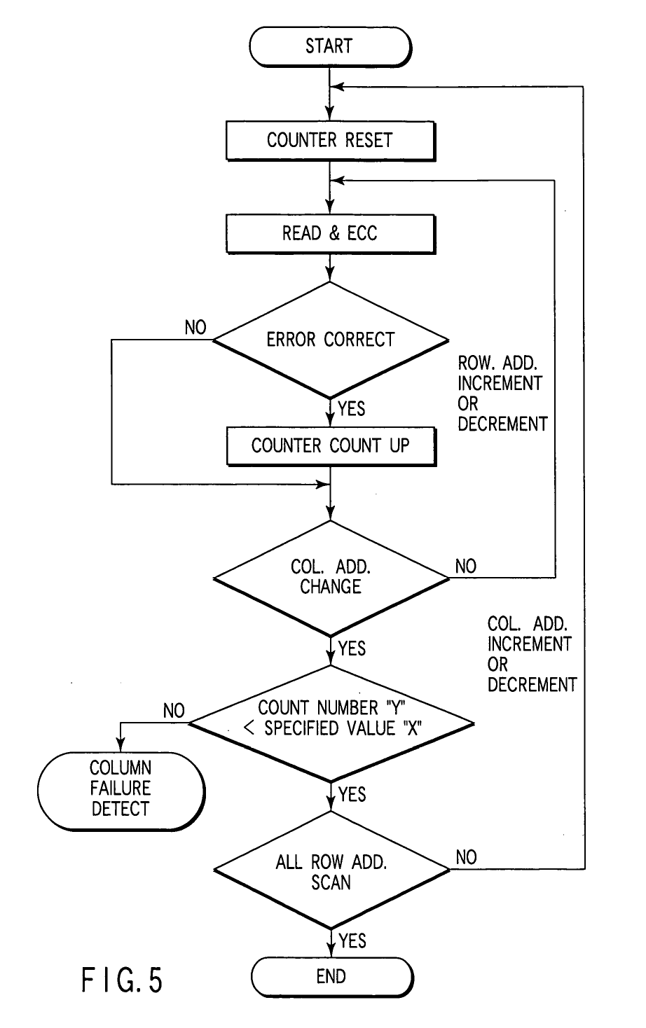

In such an arrangement, as shown in FIG. 5, the syndrome counter 18a continues to count the number of error corrections until it is reset. When the count in the syndrome counter 18a reaches the specific value (count limiting value), a column fault detect signal is output from the output circuit 19. Thereby, it becomes possible to detect a column fault such that bit faults are present at intervals on the same column.

Not only a situation in which all the bits on the same column are faulty but also a situation in which bit faults are present at intervals on the same column may be defined as a column fault in some instances. This embodiment allows such a column fault to be detected. That is, in the second embodiment, a situation in which a predetermined number of error corrections is detected while a column address set in the test circuit 17a remains unchanged, i.e., while the same column is being scanned is regarded as a column fault. Therefore, it also becomes possible to detect a column fault in which multiple bit faults are contained in a dispersed state on the same column.

As in the case of the first embodiment, the count limiting value (the number of error corrections that is regarded as a column fault) can be controlled in a programmable manner according to a command from the test device.

### Third Embodiment

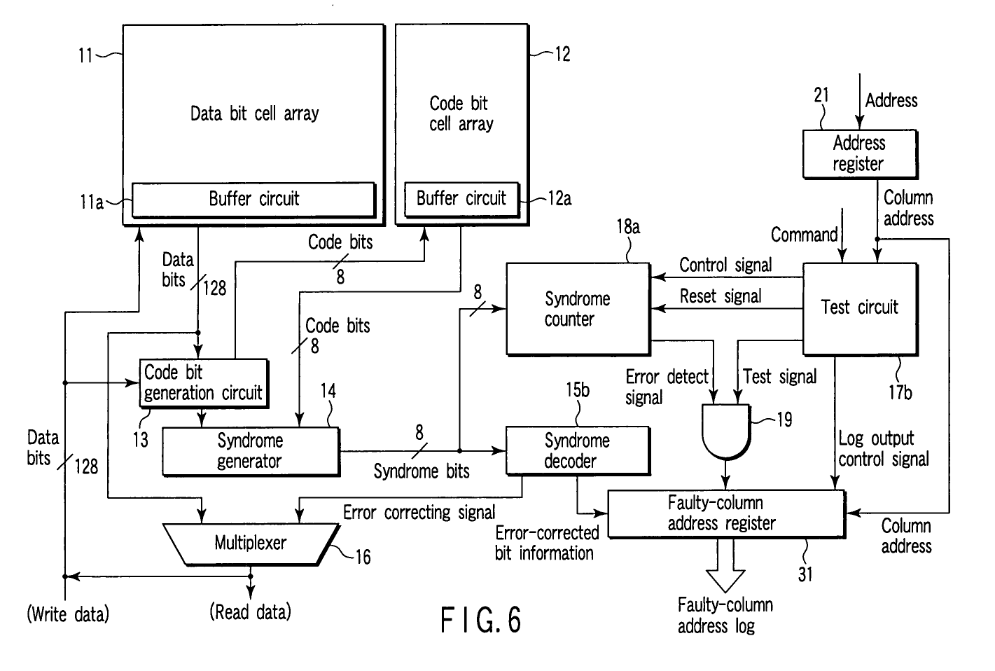

FIG. 6 shows the basic arrangement of a semiconductor memory device equipped with an ECC circuit according to a third embodiment of the present invention. The third embodiment is configured such that, in the DRAM according to the second embodiment, the address information of a column in which a fault was detected (the address of a faulty line) can be stored. In FIG. 6, corresponding parts to those in FIG. 4 are denoted by like reference numerals and detailed descriptions thereof are omitted.

In this embodiment, as shown in FIG. 6, a faulty-column address register 31 is provided which stores the address of a faulty column. The faulty-column address register 31 is supplied with a column fault detect signal from the output circuit 19 to temporarily store error-corrected bit information from a syndrome decoder 15b and a column address from the address register 21.

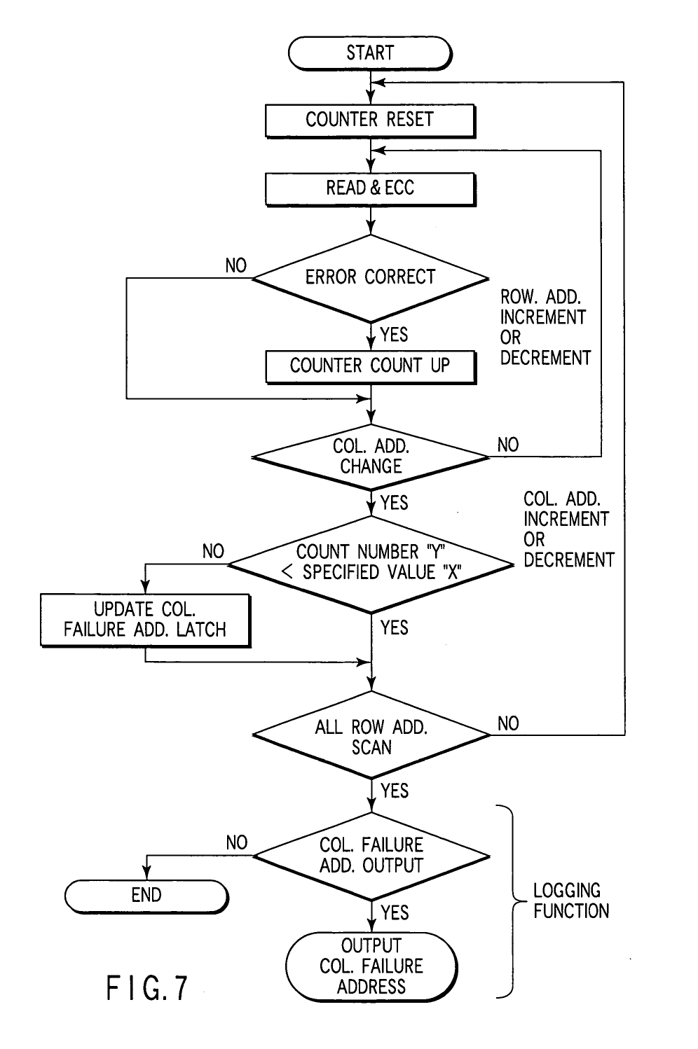

In such a configuration, as shown in FIG. 7, error corrections of the specific number “X” or more are detected while the same column is being scanned. Then, the address of the column and error-corrected bit information are latched by the faulty-column address register 31. The latched information can be output to the outside of the DRAM in response to a log output control signal output from the test circuit 17b according to entry of a specific command. It therefore becomes easy to remedy the ECC-circuit-corrected column fault by the redundancy circuit or reject the DRAM. That is, the third embodiment is configured to allow the address information of a faulty column which is subjected to error correction in the ECC circuit to be temporarily stored and its log to be read out as needed. Thus, this embodiment is effective in repairing an error-corrected column fault by the redundancy circuit.

The column address information stored in the faulty-column address register 31 is not limited to that corresponding to one column. Depending on circumstances, the capacity of the register 31 may be increased to accommodate a number of column faults.

### Fourth Embodiment

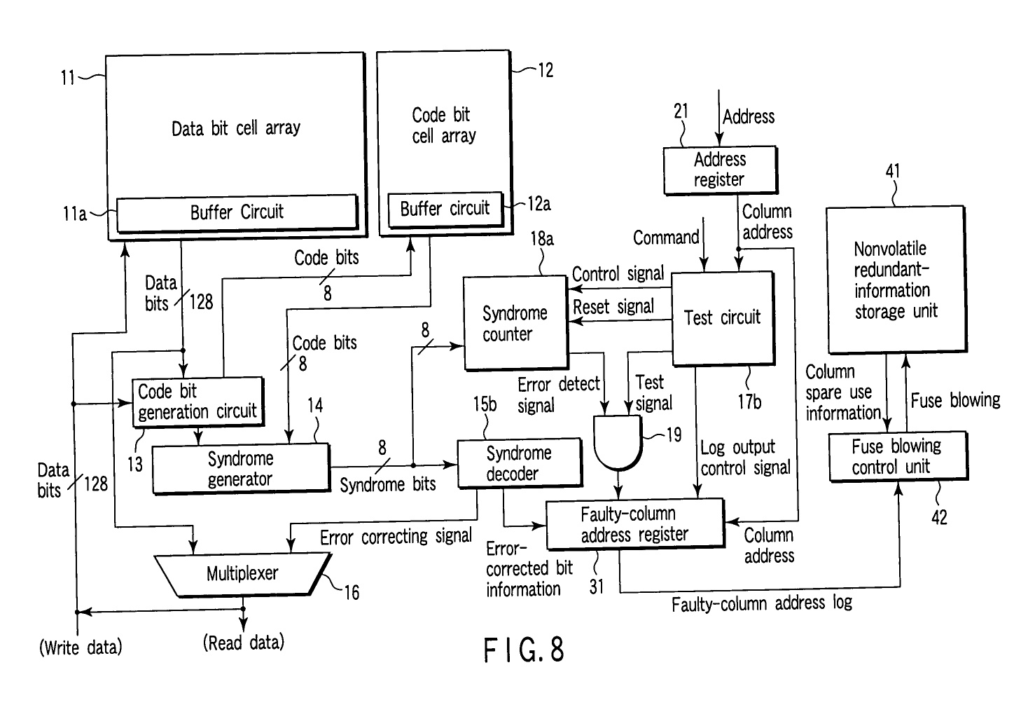

FIG. 8 shows the basic arrangement of a semiconductor memory device equipped with an ECC circuit according to a fourth embodiment of the present invention. The fourth embodiment is configured such that, in the DRAM according to the third embodiment, an error-corrected column fault can be repaired by the redundancy circuit on the basis of the stored address information of the faulty column. In FIG. 8, corresponding parts to those in FIG. 6 are denoted by like reference numerals and detailed descriptions thereof are omitted.

In this embodiment, as shown in FIG. 8, a nonvolatile redundant-information storage unit 41 is provided which holds faulty address information (redundant information) involved in repair by the redundancy circuit. The nonvolatile redundant-information storage unit 41 has a plurality of electrically disconnectable electrical fuses. Unlike laser fuses, the electrical fuses can be disconnected spontaneously within the device without need of large-scale fuse blowing equipment.

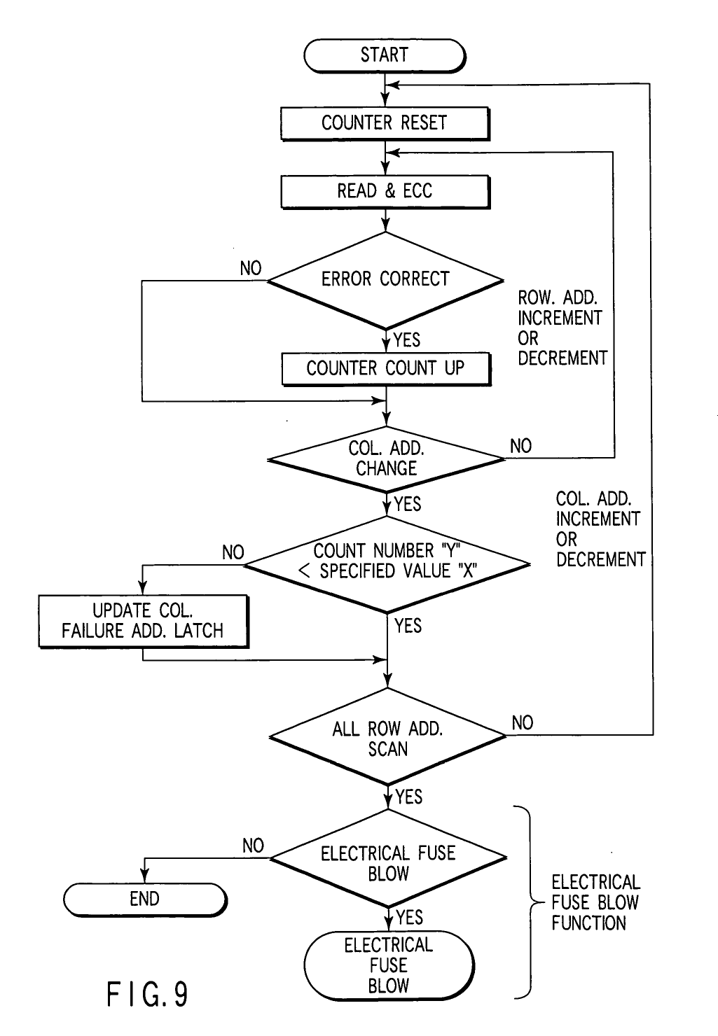

In such a configuration, the column address information stored in the faulty-column address register 31 is sent to a fuse blowing control unit 42. Column spare use information is also sent from the nonvolatile redundant-information storage unit 41 to the fuse blowing control unit 42. Based on this information, a decision is made in the fuse blowing control unit 42 as to whether or not the remedy of an additional column fault is possible in the nonvolatile redundant-information storage unit 41. If the decision is that the remedy of an additional column fault is possible, then a fuse blowing signal (faulty-column address information) involved in repair by the redundancy circuit is sent from the fuse blowing control unit 42 to the nonvolatile redundant-information storage unit 41. In this manner, a predetermined fuse in the nonvolatile redundant-information storage unit 41 is electrically disconnected. It therefore becomes possible to remedy spontaneously the detected column fault by the redundancy circuit (see FIG. 9).

Such a configuration as described above allows column faults to be remedied even in a test after packaging. That is, if there is room for remedying column faults which are error corrected by the ECC circuit through the use of the redundancy circuit, the remedy can be performed any number of times.

In the case the remedy is impossible, it is also possible to reject the corresponding DRAM.

Although the embodiments have been described in terms of the column fault detection through the RFS-pattern-based test, this is not restrictive. With semiconductor memory devices equipped with an ECC circuit, 128 columns located at intervals of 8 columns in, for example, 1024 columns may be taken to be the subject of error correction with the exception that consecutive columns are taken to be the subject of error correction. In such a case, if only eight columns in the minimum unit develop a column fault, single-bit error correction by the ECC circuit is possible; therefore, that column fault cannot be detected as a line fault. To cope with such a situation, when error corrections are made in succession or error corrections of the specific number “X” or more are made on the same column in an RFS-pattern-based test, a row fault is considered to have occurred, thereby allowing a line fault to be detected.

Although the embodiments have been described in terms of a DRAM equipped with an ECC circuit, the principles of the invention are also applicable to a static RAM (SRAM) equipped with an ECC circuit by way of example. When a test device is provided with an ECC circuit, the principles of the invention is also applicable to an NAND-type electrically erasable programmable read only memory (EEPROM) having no ECC circuit or the like.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor memory device comprising:
a data bit cell array in which a plurality of memory cells each to store a data bit is arranged;
a test circuit which detects and analyzes a command that contains test pattern information;
a syndrome counter which counts the number of error corrections which are made on data bits read from the data bit cell array in a test made on the basis of the test pattern information; and
an output circuit which outputs a line fault detect signal when the count in the syndrome counter reaches a predetermined value.

2. The semiconductor memory device according to claim 1, wherein the test circuit is adapted to set the predetermined value in the syndrome counter and be able to control the value to be set in the syndrome counter in a programmable manner according to the command.

3. The semiconductor memory device according to claim 1, wherein the syndrome counter is adapted to have the predetermined value set by the test circuit, count the number of error corrections which are made in succession on the same line, and output control information to the output circuit when the number of error corrections reaches the predetermined value to thereby cause the output circuit to produce the line fault detect signal.

4. The semiconductor memory device according to claim 1, wherein the test pattern information is information for a test based on a row first scan (RFS) pattern or information for a test based on a column first scan (CFS) pattern.

5. The semiconductor memory device according to claim 1, further comprising an error correction code (ECC) circuit which detects and corrects errors in the data bits read from the data bit cell array and a code bit cell array which stores code bits required for error detection and correction by the ECC circuit.

6. The semiconductor memory device according to claim 5, wherein the ECC circuit has a function of single-bit error correction/double-bit error detection.

7. The semiconductor memory device according to claim 1, further comprising a first address register which temporarily stores the address of a line which is the subject of the test, and wherein the syndrome counter counts the number of error corrections which are made on the line corresponding to the address stored in the first address register and outputs control information to the output circuit when the number of error corrections reaches the predetermined value to thereby cause the output circuit to produce the line fault detect signal.

8. The semiconductor memory device according to claim 7, further comprising a second address register which temporarily stores the address of a line which is the subject of the test and outputs the stored address to outside of the device as the address of a faulty line when the number of error corrections which are made on the line corresponding to the address stored in the second address register reaches the predetermined value.

9. The semiconductor memory device according to claim 8, further comprising a control circuit which makes a decision of whether it is possible to remedy the faulty line corresponding to the address output from the second address register through a redundancy circuit, and a nonvolatile storage unit which, when the control circuit decides that the remedy of the faulty line through the redundancy circuit is possible, stores redundant information for remedy through the redundancy circuit under the control of the control circuit.

10. The semiconductor memory device according to claim 9, wherein the nonvolatile storage unit includes a plurality of electrical fuses.

11. The semiconductor memory device according to claim 5, wherein the ECC circuit has a code bit generation circuit which generates the code bits on the basis of the data bits, a syndrome generator which checks the code bits generated on the basis of the data bits read from the data bit cell array with the code bits read from the code bit cell array and outputs syndrome bits which contain information concerning the presence or absence of and the position of a bit fault, a syndrome decoder which decodes the syndrome bits from the syndrome generator, and a multiplexer which corrects an error in the data bits read from the data bit cell array according to the results of decoding by the syndrome decoder.

12. A semiconductor memory device comprising:
a data bit cell array in which a plurality of memory cells are arranged to store data bits;
an error correction code (ECC) circuit which detects and corrects errors in data bits read from the data bit cell array;
a code bit cell array which stores code bits required for the ECC circuit to perform error detection and correction;
a test circuit which detects and analyzes a command containing test pattern information and a count limiting value for line fault detection;
a syndrome counter which counts the number of error corrections that are made on data bits read from the data bit cell array in a test made under the test pattern information;
an output circuit which outputs a line fault detect signal when the count in the syndrome counter reaches the count limiting value; and
a first address register which temporarily stores the address of a line which is the subject of the test.

13. The semiconductor memory device according to claim 12, wherein the syndrome counter is adapted to count the number of error corrections which are made on the line corresponding to the address stored in the first address register and output control information to the output circuit when the counted number of error corrections reaches the count limiting value, to thereby cause the output circuit to produce the line fault detect signal.

14. A semiconductor memory device comprising:
a data bit cell array in which a plurality of memory cells are arranged to store data bits;
an error correction code (ECC) circuit which detects and corrects errors in data bits read from the data bit cell array;
a code bit cell array which stores code bits required for the ECC circuit to perform error detection and correction;
a test circuit which detects and analyzes a command containing test pattern information and a count limiting value for line fault detection;
a syndrome counter which counts the number of error corrections that are made on data bits read from the data bit cell array in a test made under the test pattern information;
an output circuit which outputs a line fault detect signal when the count in the syndrome counter reaches the count limiting value;
a first address register which temporarily stores the address of a line which is the subject of the test; and
a second address register which temporarily stores the address of a line which is the subject of the test and outputs the stored address to outside of the device as the address of a faulty line when the count in the syndrome counter reaches the count limiting value.

15. The semiconductor memory device according to claim 14, wherein the syndrome counter is adapted to count the number of error corrections which are made on the line corresponding to the address stored in the first address register and output control information to the output circuit when the counted number of error corrections reaches the count limiting value, to thereby cause the output circuit to produce the line fault detect signal.

16. A semiconductor memory device according to claim 14, further comprising:
a control circuit which makes a decision of whether it is possible to remedy the faulty line corresponding to the address output from the second address register through a redundancy circuit; and
a nonvolatile storage unit which, when the control circuit decides that the remedy of the faulty line through the redundancy circuit is possible, stores redundant information for remedy through the redundancy circuit under the control of the control circuit.

17. The semiconductor memory device according to claim 16, wherein the syndrome counter is adapted to count the number of error corrections which are made on the line corresponding to the address stored in the first address register and output control information to the output circuit when the counted number of error corrections reaches the count limiting value, to thereby cause the output circuit to produce the line fault detect signal.
